(19) United States
(12) Patent Application Publication
(10) Pub. No.: US 2026/0122857 A1
(43) Pub. Date: Apr. 30, 2026

(54) Lifting Mechanism for Pluggable Modules

(71) Applicant: Arista Networks, Inc., Santa Clara, CA (US)

(72) Inventors: Youngbae PARK, Milpitas, CA (US); Robert Morris WILCOX, Saratoga, CA (US); Ya-Chung JAN, Cupertino, CA (US)

(21) Appl. No.: 18/933,827

(22) Filed: Oct. 31, 2024

(51) Int. Cl. H05K 7/20

(52) U.S. Cl. CPC H05K 7/2049; H05K 7/20254; H05K 7/20136

(57) ABSTRACT

A pluggable module cage assembly includes a heatsink that is fastened, joined, or otherwise securely fixed to the cage or host board, making the heatsink substantially immovable relative to the cage or host board. A portion of the surface of the heatsink is exposed to the interior volume of the cage so that it can physically and thermally contact the pluggable module. The cage assembly includes a lifting mechanism that operates to lift a pluggable module when the module is plugged into the cage. The lifting mechanism lifts the module toward the heatsink to push the module with a controlled force against the exposed portion of the surface of the heatsink to make thermal contact.

### BACKGROUND

The present disclosure is directed to heat dissipation for pluggable modules (modules) in a network device. Pluggable modules are user replaceable modular devices that can be plugged into the host system. Pluggable modules include OSFP (Octal Small Form Factor Pluggable), OSFP-RHS (OSPF-Riding Heatsink), QSFP-DD (Quad Small Form Factor Pluggable Double Density), QSFP, SFP and CFP (100G Form Factor Pluggable). Pluggable modules generate heat during operation that needs to be removed. Designs typically include placing a suitable heat exchange element (heatsink or cold plate) on the cage that receives the pluggable module. The heatsink is held in place on the cage by a spring-loaded attachment such as a spring clip so it can press against a module when it is plugged (inserted) into the cage. The cage includes an opening that exposes a portion of the heatsink to the inserted module. In other typical designs, there is a compliant gap-filling material between the exposed portion of the heatsink and the inserted module to thermally couple these components.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, makes apparent to those of skill in the art how embodiments in accordance with the present disclosure may be practiced. Similar or same reference numbers may be used to identify or otherwise refer to similar or same elements in the various drawings and supporting descriptions. In the accompanying drawings:

FIG. 1 shows an example of a network device (host system) that can accommodate embodiments in accordance with the present disclosure.

FIG. 2 shows a cutaway side view of a network device, illustrating aspects of the present disclosure.

FIGS. 3A and 3B illustrate additional aspects of the present disclosure.

FIGS. 4A, 4B, 4C, 4D, 4E, 4F illustrate aspects of a first embodiment in accordance with the present disclosure.

FIGS. 5A, 5B, 5C, 5D, 5E illustrate aspects of a second embodiment in accordance with the present disclosure.

FIGS. 6A, 6B, 6C, 6D, 6E, 6F, 6G, 6H illustrate aspects of a third embodiment in accordance with the present disclosure.

FIGS. 7A, 7B, 7C, 7D, 7E illustrate aspects of a fourth embodiment in accordance with the present disclosure.

FIGS. 8A, 8B illustrate aspects of a fifth embodiment in accordance with the present disclosure.

FIGS. 9A, 9B illustrate aspects of a sixth embodiment in accordance with the present disclosure.

FIGS. 10A, 10B, 10C, 10D, 10E illustrate aspects of a seventh embodiment in accordance with the present disclosure.

FIGS. 11A, 11B, 11C illustrate aspects of an eighth embodiment in accordance with the present disclosure.

FIGS. 12A, 12B, 12C illustrate aspects of a ninth embodiment in accordance with the present disclosure.

FIGS. 13A, 13B illustrate aspects of a tenth embodiment in accordance with the present disclosure.

### DETAILED DESCRIPTION

Network devices include heat dissipation equipment (heatsinks, cold plate, etc.) to remove the heat generated during operation of a pluggable module. As explained above, current solutions typically include placing a suitable heat exchange element (heatsink) on the cage that receives the pluggable module (module). The heatsink is mounted to the cage by a spring-loaded attachment such as a spring clip. The cage includes an opening that exposes a portion of the heatsink to the interior volume of the cage. The spring loaded attachment presses the heatsink against an inserted module in order to achieve good thermal contact. Because the position of the module within the cage can vary, the spring loaded attachment ensures thermal contact between the heatsink and the module.

When a module is plugged (inserted) into the cage, the module pushes against the heatsink, displacing the heatsink from its resting position. The restoring force of the spring-loaded attachment presses on the heatsink so that the portion of the heatsink exposed through the cage opening comes into physical contact with and presses against a surface of the module, thereby creating good thermal contact. Heat generated during operation of the module can then be conducted away from the module to the heatsink via thermally contacting surfaces. When the module is unplugged (removed) from the cage, the heatsink is restored to its resting position. Accordingly, the heatsink is subject to vertical displacement (up and down movement) when a module is inserted and removed.

Liquid cooled heatsinks (cold plates) present a challenge. In the case of a liquid cooled heatsink (cold plate), the liquid passage (tubing) that supplies cooling fluid to the heatsink is subjected to the up and down movement of the heatsink. As such, the liquid passage is typically designed using flexible tubing which requires extra space for the needed length to accommodate the flexible tubing, bulky connectors, etc. In addition, in the case of multiple modules, each module will have its own liquid cold plate. Implementation of multiple liquid cold plates can be challenging due to the physical space requirement to accommodate the flexible tubing of the multiple liquid cold plates.

In other typical designs, the heatsink (e.g., air cooled, liquid cold plate, etc.) uses a thermal gap-filling material which can fill the gap between the heatsink and the pluggable module to improve thermal contact. The gap distance can vary for different modules due to manufacturing tolerance. To allow for repeated insertion and removal of a module, the gap-filling material should be able to withstand repeated sliding of the module and should be compliant to accommodate gap distances of different modules. Thermal performance of such existing gap-filling materials is limited and hinders heat dissipation.

In accordance with the invention, a pluggable module cage assembly includes a heatsink that is fastened, joined, or otherwise securely fixed to the cage or host PCB (printed circuit board, also referred to as host electronics board, host PCB assembly, and the like), making the heatsink substantially immovable relative to the cage or host PCB. A portion of the surface of the heatsink is exposed to the interior volume of the cage so that it can physically and thermally contact the pluggable module. The cage assembly includes a lifting mechanism that operates to lift a pluggable module when the module is plugged into the cage. The lifting mechanism lifts, moves, or otherwise displaces the module toward the heatsink to push the module with a controlled force against the exposed portion of the surface of the heatsink to make a thermal contact. A gap-filling material is not required because the potential gap between the heatsink and the module is eliminated as the module is positioned to press against the heatsink to establish good conductive thermal contact.

Embodiments of the lifting mechanism include spring-loaded variations and slider-activated variations. Heatsinks can include a plate having heat dissipation fins, a liquid cold plate, etc. Additional aspects of the present disclosure include:
The cage assembly can be press-fit onto the host PCB.
The cage assembly can be screw-mounted onto the host PCB, rather than press-fit. In this case, the host PCB does not need to extend all the way to the front panel.
A ganged cage assembly is a cage sub-system comprising multiple ports (cage assemblies) arranged side by side for receiving pluggable modules. A single heatsink or cold plate unit can be attached to the top of the ganged cage assembly that spans the width of the assembly. Each port includes its own lifting mechanism for its respective pluggable module.
   The cold plate does not need a bulky flexible liquid passage subassembly. Instead, the liquid passage can be constructed using copper tubing which can better accommodate tight spaces.
   The heatsink unit can extend to the front panel to receive an inflow of ambient air through cutouts in the front panel for cooling.
   In some use cases, the heatsink unit can extend through the front panel and be exposed directly to ambient air.
Two ganged cage assemblies can be assembled in a belly-to-belly configuration.
Multiple ganged cage assemblies can be stacked to create a stacked assembly.
Two stacked assemblies can be assembled into a belly-to-belly configuration and extend to the front panel (or in some cases extends through the front panel).

Substantially fixing the heatsink relative to the cage substantially eliminates any movement of the heatsink when the module is plugged and unplugged from the cage. This is especially useful in the case of liquid cold plate type heatsinks in a ganged cage configuration. A single cold plate device can be used to provide cooling for all the cage subassemblies. Individual cold plates do not need to be provided for each individual pluggable module, thus simplifying the mechanical design.

In accordance with the present disclosure, an inserted module is held in place by a spring loaded mechanism that pushes the module against the heatsink to make thermal contact with the heatsink without having to use gap-filling material and without substantially moving the heatsink.

In the following description, for purposes of explanation, numerous examples and specific details are set forth in order to provide a thorough understanding of embodiments of the present disclosure. Particular embodiments as expressed in the claims may include some or all of the features in these examples, alone or in combination with other features described below, and may further include modifications and equivalents of the features and concepts described herein.

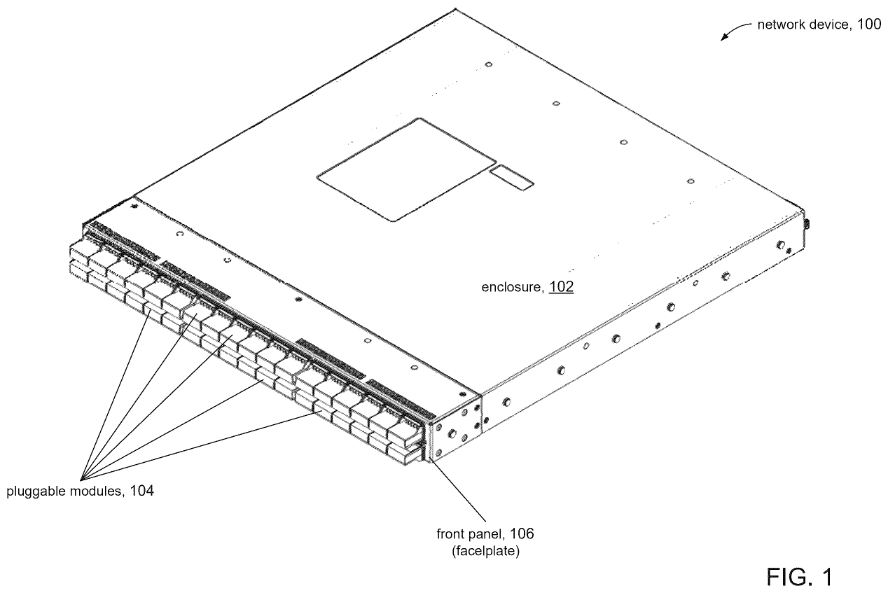

FIG. 1 is an example of a network device (host system) that can embody aspects of the present disclosure. Network device 100 comprises an enclosure (housing, chassis) 102 that houses the mechanical elements and electronic components of the device. Data input and output with network device 100 is provided by pluggable modules 104. The example shows two rows of pluggable modules, although other embodiments of the network device can include more or fewer rows of pluggable modules. Enclosure 102 includes a front panel (faceplate) 106 having cutouts through which the pluggable modules are inserted.

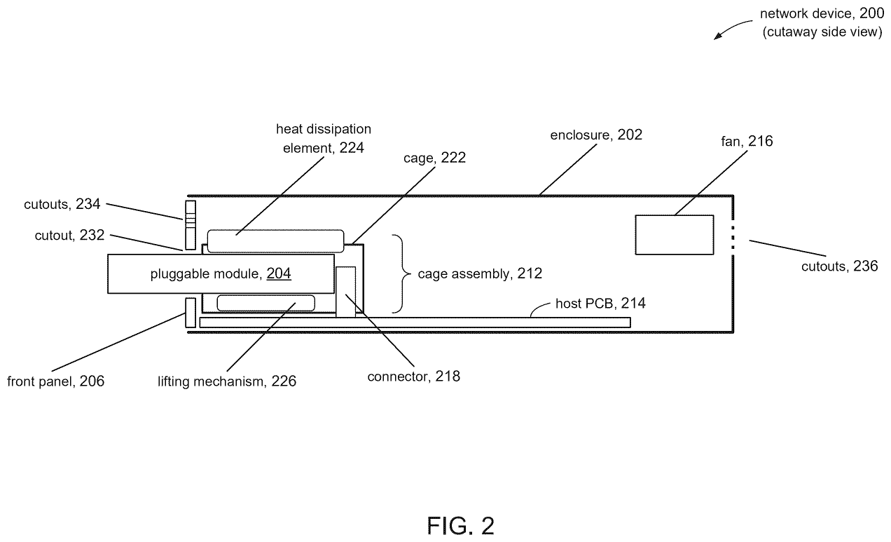

FIG. 2 is a cutaway side view of a network device 200 schematically illustrating components in the network device. Network device 200 comprises enclosure 202 and front panel 206. Enclosure 202 houses components such as host PCB 214, fan 216, and other equipment. In the configuration shown, PCB 214 extends to front panel 206, although in other embodiments the PCB may not extend all the way to the front panel. Cage assembly 212 is mounted on PCB 214. Although not shown in the figure it will be understood that switching and supporting electronics are also mounted on the PCB.

In accordance with the present disclosure, cage assembly 212 comprises cage 222, heat dissipation element 224, and lifting mechanism 226. The figure illustrates pluggable module 204 is inserted through cutout 232 of front panel 206 and received in cage 222. Pluggable module 204 plugs into connector 218 to provide signal paths between electronics in the pluggable module and switching electronics mounted on PCB 214.

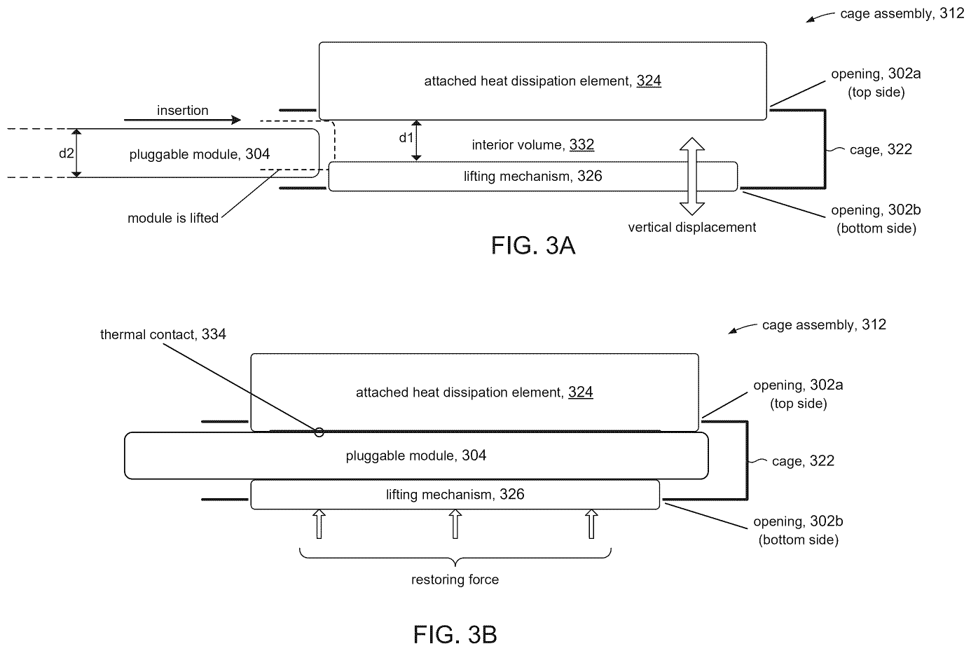

FIGS. 3A and 3B are simplified schematic illustrations that show additional details of a cage assembly 312 in accordance with the present disclosure. In some embodiments, cage assembly 312 comprises cage 322, heat dissipation element 324, and lifting mechanism 326. In accordance with the present disclosure, heat dissipation element 324 is fixedly attached to cage 322. Any suitable method can be used to attach heat dissipation element 324 to cage 322 including, but not limited to, gluing, spot welding, mechanical attachment such as screw-mounted, riveting, crimping, and so on. In this way, heat dissipation element 324 is rendered substantially immovable relative to cage 322. In other embodiments, the heat dissipation element can be fixedly attached to the host PCB so as to remain substantially immovable relative to the PCB; e.g., mounting directly to the PCB with a standoff.

Cage 322 includes an opening 302a through its top side to expose a portion of heat dissipation element 324 to interior volume 332 of the cage.

In accordance with some embodiments of the present disclosure, lifting mechanism 326 is a spring loaded mechanism and is movably attached to a bottom side of cage 322, allowing vertical displacement of the lifting mechanism relative to the cage as indicated in FIG. 3A. Examples of spring components in lifting mechanism 326 are described below. A portion of lifting mechanism 326 extends into interior volume 332 of cage 322 through an opening 302b formed through the bottom side (cage floor) of the cage. In other embodiments, lifting mechanism 326 is a slider activated mechanism.

FIGS. 3A and 3B illustrate an example of the operation of lifting mechanism 326 when pluggable module 304 is plugged (inserted) into cage 322. It will be understood that the dimensions shown in the figures are not to scale and exaggerated to more clearly illustrate the operation.

FIG. 3A shows pluggable module 304 being plugged into cage 322. Before pluggable module 304 engages lifting mechanism 326, the lifting mechanism can be said to be in its rest position. In some embodiments, the components of cage assembly 312 can be designed with dimensions such that when lifting mechanism 326 is in its rest position (i.e., a pluggable module is not plugged in), the separation distance d1 between the lifting mechanism and heat dissipation element 324 is less than the height d2 of a pluggable module.

When pluggable module 304 first engages lifting mechanism 326 at the beginning of an insertion operation, the pluggable module may be upwardly displaced toward heat dissipation element 324 due to mechanical resistance of the lifting mechanism. As the insertion continues, pluggable module 304, by virtue of its height d2 being greater than the resting separation distance d1, will push on both heat dissipation element 324 and lifting mechanism 326. Because heat dissipation element 324 is fixedly attached to cage 322 (or in some embodiments to the PCB), the heat dissipation element will remain substantially stationary relative to the cage (or PCB) when pluggable module 304 pushes on it. On the other hand, because lifting mechanism 326 is spring loaded, it will be vertically displaced downward relative to cage 322 when pluggable module 304 pushes on it. This will cause the spring component of lifting mechanism 326 to exert a restoring force on pluggable module 304, pushing the pluggable module against heat dissipation element 324 and making thermal contact 334 with the heat dissipation element. In some embodiments, thermal contact 334 between pluggable module 304 and heat dissipation element 324 may be enhanced by the use of a thermal paste or other suitable thermally conductive material. When pluggable module 304 is unplugged and removed from cage 322, the restoring force of the spring component in lifting mechanism 326 will return the lifting mechanism back to its rest position to re-establish the resting separation distance d1, as shown in FIG. 3A.

The discussion will now turn to a description of example embodiments to illustrate various aspects of a cage assembly and cage subsystems in accordance with the present disclosure.

### Embodiment 1

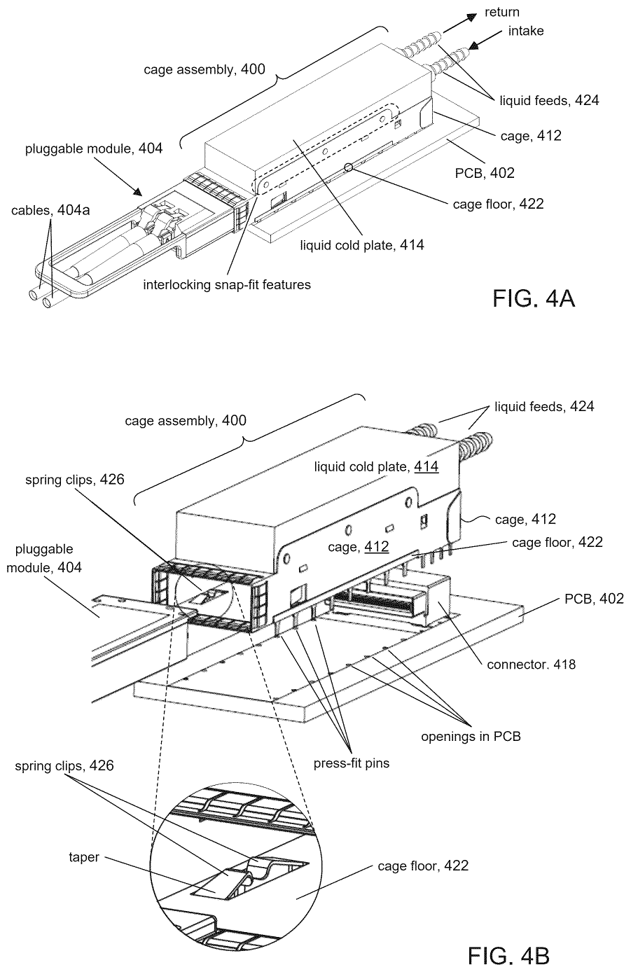

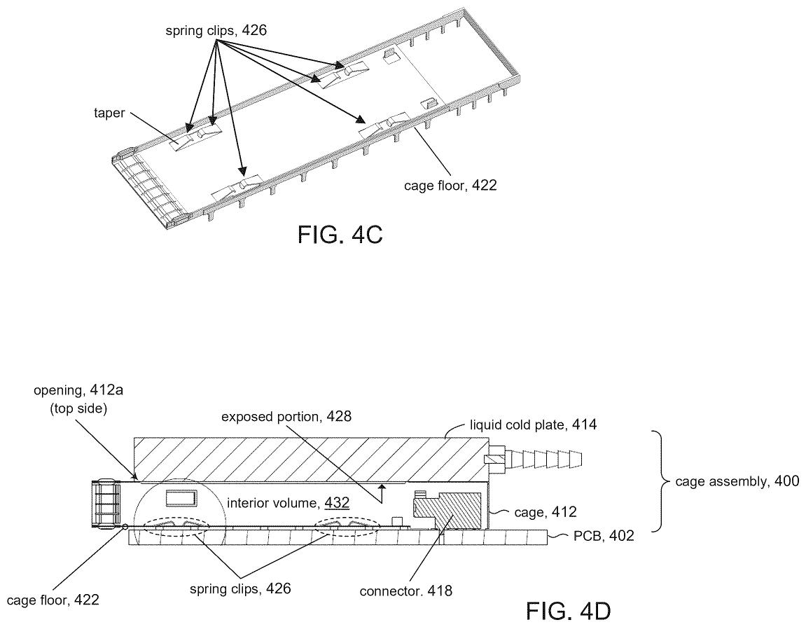

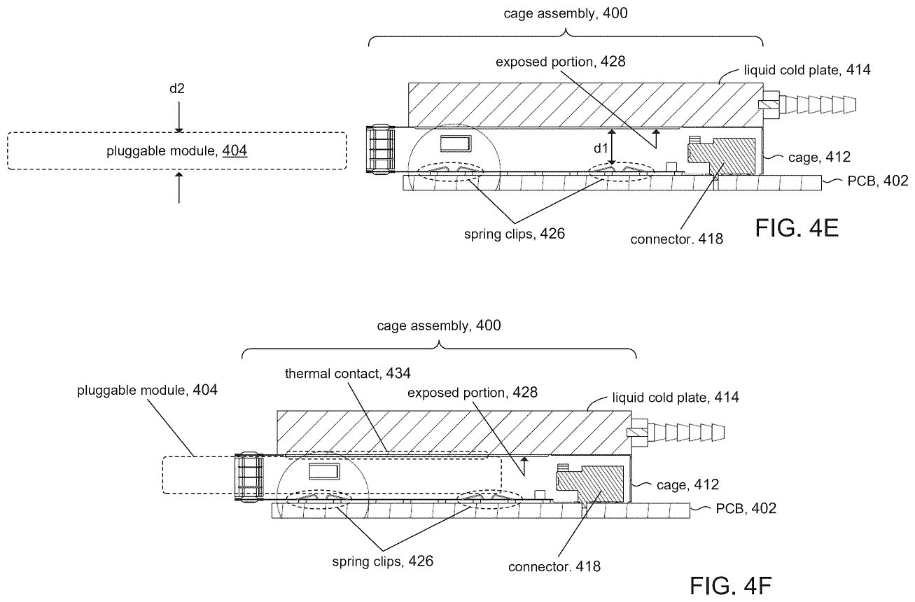

FIGS. 4A-4F show a cage assembly in accordance with a first example embodiment of the present disclosure. Cage assembly 400 is shown mounted on host PCB 402. Pluggable module 404 is shown plugged into cage 412 of cage assembly 400. Cables 404a can be used to connect external devices (not shown) to pluggable module 404.

Cage assembly 400 comprises cage 412 and a heat dissipation element 414 known as a liquid cold plate. It will be appreciated that any suitable heat dissipation technique can be used; e.g., air cooled devices, etc. Liquid cold plate technology is known. Briefly, liquid cold plate 414 includes liquid feeds 424 for connecting to a cool fluid intake line (not shown) and a heated fluid return line (not shown). Cool liquid enters liquid cold plate 414 via the intake line, circulates through the liquid cold plate, absorbing heat generated during operation of pluggable module 404, and exits to the return line where the heated liquid can be cooled by a heat exchange unit (not shown) and returned on the intake line as cool liquid.

As illustrated in FIGS. 4B and 4C, in this first example embodiment, the lifting mechanism comprises spring clips 426 formed in or attached to cage floor 422 of cage 412. Spring clips 426 are resilient so that when they are pushed down upon, they will exert an opposing restoring force. The restoring force can be controlled by the geometry of spring clips 426 and the material of cage floor 422 from which the spring clips are formed.

Cage 412 and liquid cold plate 414 have corresponding interlocking snap-fit features to provide a fixed attachment of the liquid cold plate to the cage so that the liquid cold plate is substantially immovable relative to the cage. It will be appreciated that any suitable attachment mechanism can be used such as gluing, spot welding, mechanical fastening (e.g., riveted, screw-mounted, etc.), and so on to provide a fixed, static attachment of liquid cold plate 414 to the cage 412. In other embodiments, liquid cold plate 414 can be fixedly attached to PCB 402 so as to remain substantially immovable relative to the PCB; e.g., by mounting the liquid cold plate directly to the PCB with a standoff.

Cage floor 422 has press-fit pins that press into corresponding openings in PCB 402 to mount cage assembly 400 on the PCB.

Connector 418 can be mounted on PCB 402. Pluggable module 404 can plug into connector 418 to provide electrical connections to switching and supporting electronics (not shown) on PCB 402.

FIG. 4D is a cutaway side view of cage assembly 400. A portion 428 of the surface of liquid cold plate 414 is exposed to interior volume 432 through an opening of cutout 412a made through the top side of cage 412 so that the liquid cold plate can make physical and thermal contact with pluggable module 404. In some embodiments, liquid cold plate 414 itself can serve as the top side of cage 412.

FIG. 4E illustrates the resting separation distance d1 between exposed portion 428 of liquid cold plate 414 and spring clips 426. The components of cage assembly 400 can be dimensioned so that the height d2 of pluggable module 404 is greater than the resting separation distance d1. Referring to FIG. 4F, in operation, when pluggable module 404 is inserted into cage 412 and engages spring clips 426, the pluggable module will be upwardly displaced toward liquid cold plate 414 by virtue of the resiliency of spring clips 426. The spring clips at the entrance of cage 412 can have a taper (slope) to reduce interfering with pluggable module 404 during an insertion operation; e.g., FIG. 4B.

Because the height d2 of pluggable module 404 is greater than the resting separation distance d1 between spring clips 426 and liquid cold plate 414, the pluggable module will push on both the liquid cold plate and the spring clips. Because liquid cold plate 414 is substantially immovable relative to cage 412, the liquid cold plate will not be vertically displaced when pushed on by pluggable module 404. However, spring clips 426 will deform, and being resilient, the spring clips will exert a restoring force that pushes the pluggable module upward against liquid cold plate 414 to establish thermal contact 434 with the liquid cold plate.

Connector 418 makes an electrical connection with pluggable module 404 when it is plugged in. The pluggable module, connector, and the electrical contact area can deflect under load by a small amount without interrupting the electrical connection. In accordance with the present disclosure, the lifting mechanism, in this case spring clips 426, can be designed to provide sufficient force to overcome the force required to deflect the combination of pluggable module, connector, and electrical contact so that the pluggable module can still be lifted and pushed against the heatsink to make good thermal contact with the heatsink. As noted above, the restoring/pushing force of spring clips 426 can be controlled by their shape and by the type of metal from which the spring clips are formed (e.g., cage floor 422).

Referring again to FIG. 4A, when cable 404a is plugged into pluggable module 404, the cable may hang from the pluggable module, exerting a downward pulling force on the pluggable module. Spring clips 426, can be designed to further take into account the force required to overcome the downward pull of a hanging cable in order to maintain adequate thermal contact between pluggable module 404 and liquid cold plate 414.

### Embodiment 2

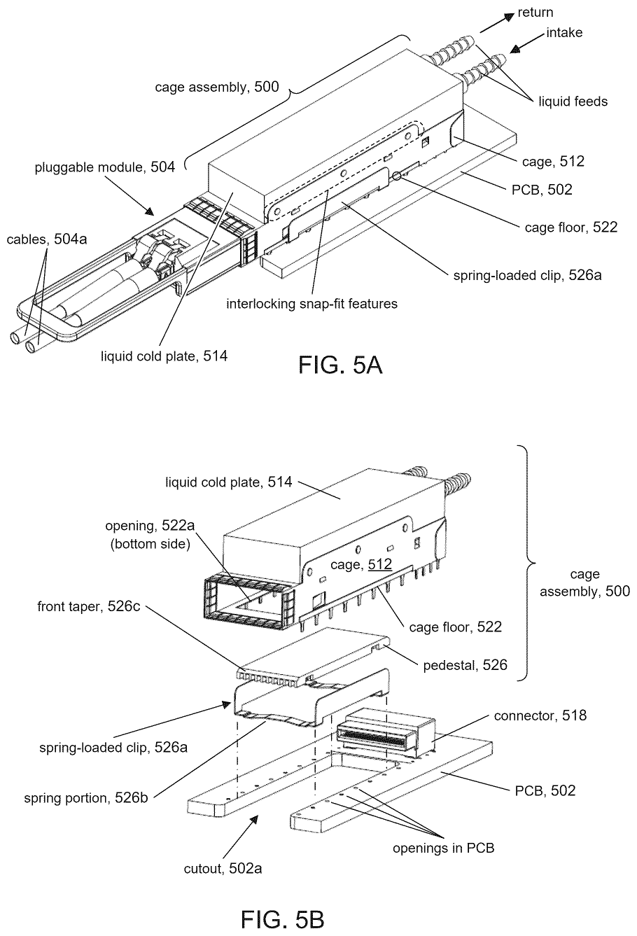

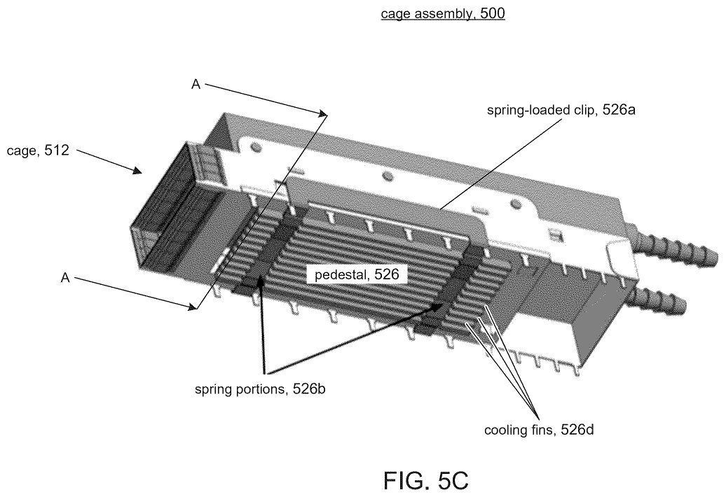

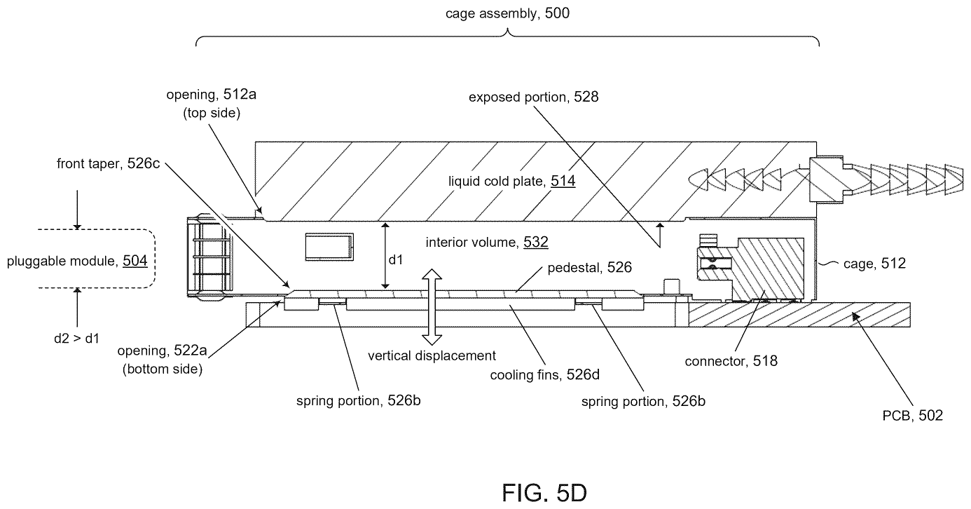

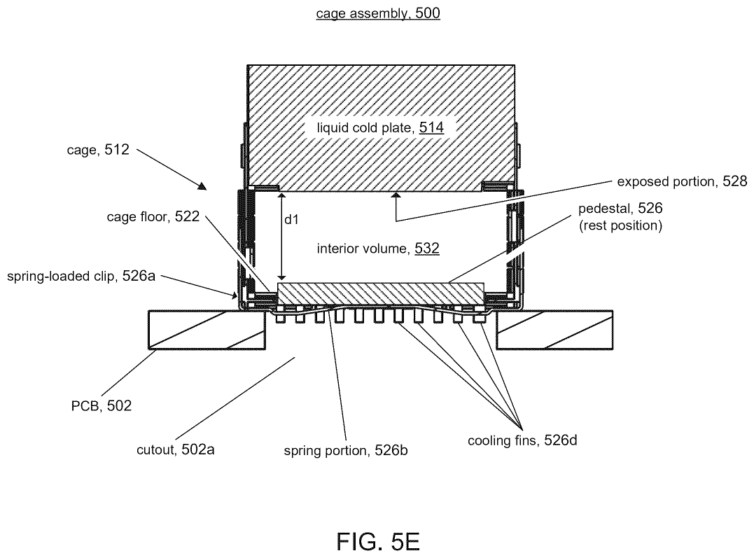

FIGS. 5A-5E show a cage assembly in accordance with a second example embodiment of the present disclosure. Cage assembly 500 is shown mounted on host PCB 502. Pluggable module 504 is shown plugged into cage 512 of cage assembly 500. Cables 504a can be used to connect external devices (not shown) into pluggable module 504.

Cage assembly 500 comprises cage 512 and a heat dissipation element which in this embodiment is liquid cold plate 514. It will be appreciated, however, that any suitable heat dissipation technique can be used. Liquid cold plate technology is known and has been briefly described above in connection with FIG. 4A.

As illustrated in FIGS. 5B and 5C, in this second example embodiment, the lifting mechanism is spring loaded pedestal 526. Pedestal 526 can be secured to cage 512 using spring loaded clip 526a; the clip supports the pedestal and clips onto the outside of the cage. Spring loaded clip 526a includes spring portions 526b which hold pedestal 526 in position relative to cage 512. Pedestal 526 extends into interior volume 532 (FIG. 5D) of cage 512 through (bottom) opening 522a formed through cage floor 522, allowing the pedestal to move vertically into and out of the interior volume of the cage.

Cage 512 and liquid cold plate 514 have corresponding interlocking snap-fit features to provide a fixed attachment of the liquid cold plate to the cage so that the liquid cold plate is substantially immovable relative to the cage. It will be appreciated that any suitable attachment mechanism can be used such as gluing, spot welding, mechanical fastening (e.g., riveted, screw-mounted, etc.), and so on. In other embodiments, liquid cold plate 514 can be fixedly attached to PCB 502 so as to remain substantially immovable relative to the PCB; e.g., by mounting the liquid cold plate directly to the PCB with a standoff.

Cage floor 522 has press-fit pins that can press into corresponding openings in PCB 502 to mount cage assembly 500 on the PCB.

Connector 518 is mounted on PCB 502. Pluggable module 504 can plug into connector 518 to provide electrical connections to switching and supporting electronics (not shown) on PCB 502.

FIG. 5D is a side cutaway view illustrating additional details of cage assembly 500. A portion 528 of the surface of liquid cold plate 514 is exposed to interior volume 532 through (upper) opening 512a at the top of cage 512 allowing the cold plate to make physical and thermal contact with pluggable module 504 when it is plugged into the cage. In some embodiments, liquid cold plate 514 itself can serve as the top side of cage 512.

As noted above, pedestal 526 extends into interior volume 532 of cage 512 through opening 522b in cage floor 522, allowing the pedestal to move vertically into and out of the interior volume of the cage. FIG. 5D, illustrates a resting separation distance d1 between exposed portion 528 of liquid cold plate 514 and pedestal 526 in the rest position (i.e., no pluggable module plugged in).

When pluggable module 504, having a height d2>d1, is inserted into cage 512 and engages pedestal 526, the pluggable module will be upwardly displaced toward liquid cold plate 514. Pedestal 526 can include a front taper (slope) 526c to reduce interfering with pluggable module 504 as it is being inserted. Because the height d2 of pluggable module 504 is greater than the resting separation distance d1 between pedestal 526 and liquid cold plate 514, the pluggable module will push on both the liquid cold plate and the pedestal. As explained, liquid cold plate 514 is substantially immovable relative to cage 512 and so will not be displaced when pushed on by pluggable module 504. However, when pluggable module 504 pushes on pedestal 526 this will deform spring portions 526b. Because spring portions 526b exhibit resiliency, they will exert a restoring force that pushes the pluggable module against liquid cold plate 514 to create thermal contact with the liquid cold plate. The restoring force of spring portions 526b can be controlled by their geometry and the material used to form the spring portions.

FIG. 5E is a cutaway view along view line A-A shown in FIG. 5C. The figure shows spring loaded clip 526a carries pedestal 526, wraps around cage 512 and clips on to the sides of the cage. Spring portions 526b have a convex profile that bulges into interior volume 532 of cage 512 and in the rest position pushes pedestal 526 into the interior volume of the cage.

Pedestal 526 can include cooling fins 526d that are exposed through the bottom of cage 512. Cooling fins 526d can provide additional air cooling in a network device (FIG. 2) that has air cooling capability. Cutout 502a in PCB 502 accommodates cooling fins 526d by providing space for the cooling fins to move into when pedestal 526 is displaced downward by a pluggable module.

As noted above in connection with the first embodiments, connector 518 (e.g., FIG. 5D) can pivot or flex in order to be reoriented so as to accommodate the vertical displacement of pluggable module 504 as it is being plugged in. The lifting mechanism, in this case spring loaded pedestal 526, can be designed to take into account the force required to overcome any mechanical insertion resistance presented by connector 518. The restoring/pushing force of pedestal 526 can be controlled by the shape and type of metal used for spring loaded clip 526a.

Referring again to FIG. 5A, when cable 504a is plugged into pluggable module 504, the cable may exert a downward pulling force on the pluggable module. Spring loaded clip 526, can be designed to further take into account the force required to overcome the downward pull of a hanging cable in order to maintain adequate thermal contact between pluggable module 504 and liquid cold plate 514.

### Embodiment 3

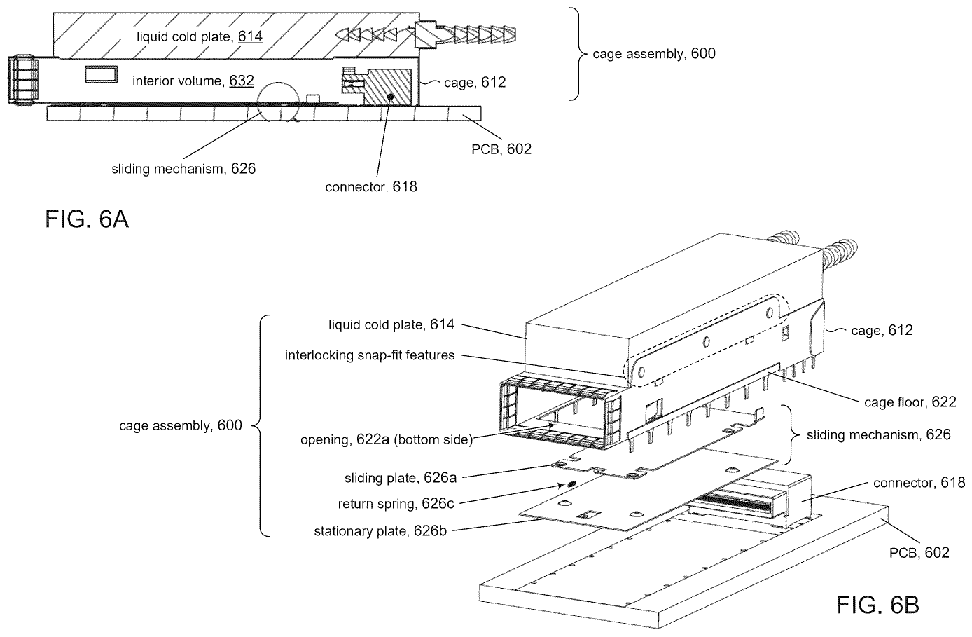

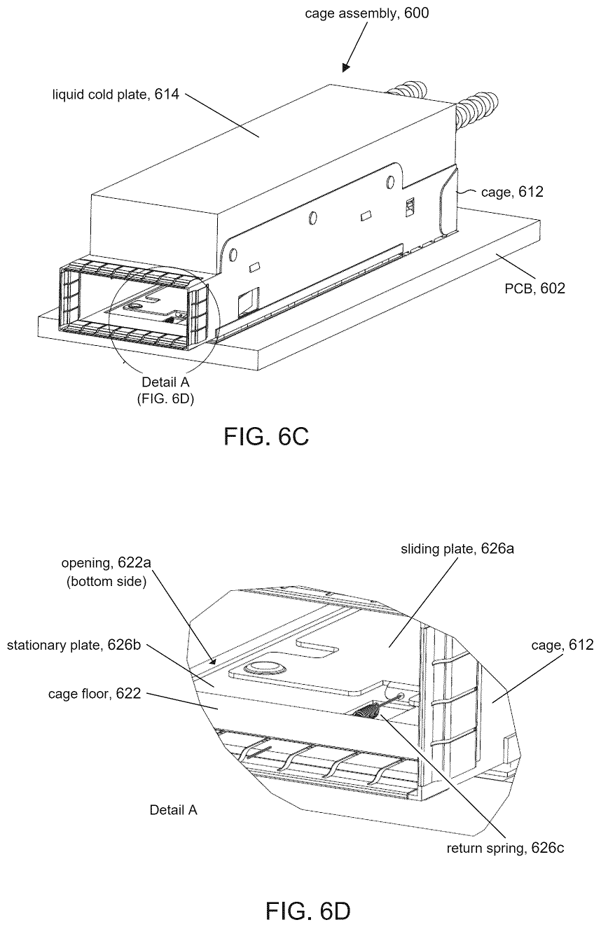

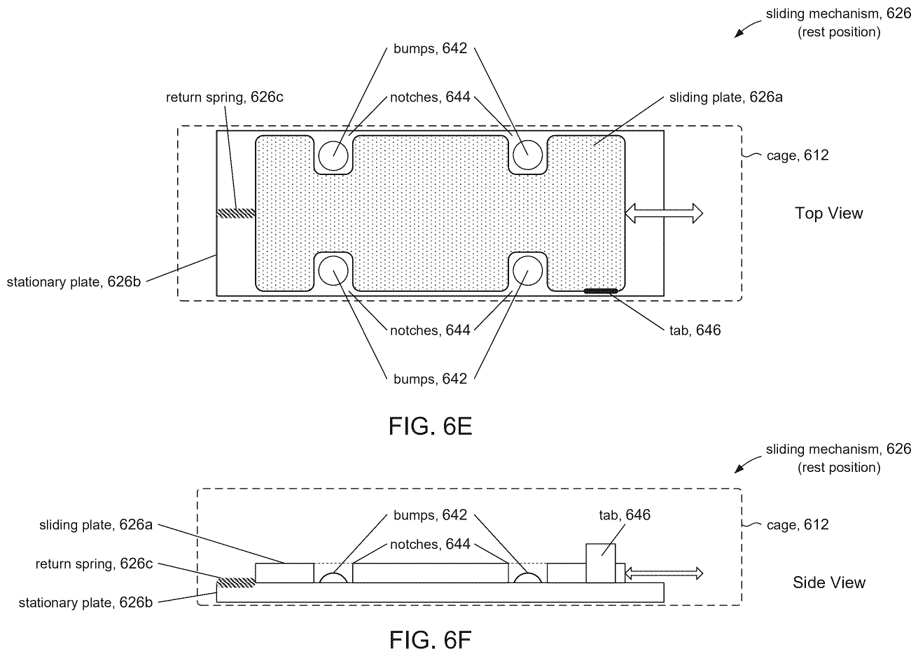

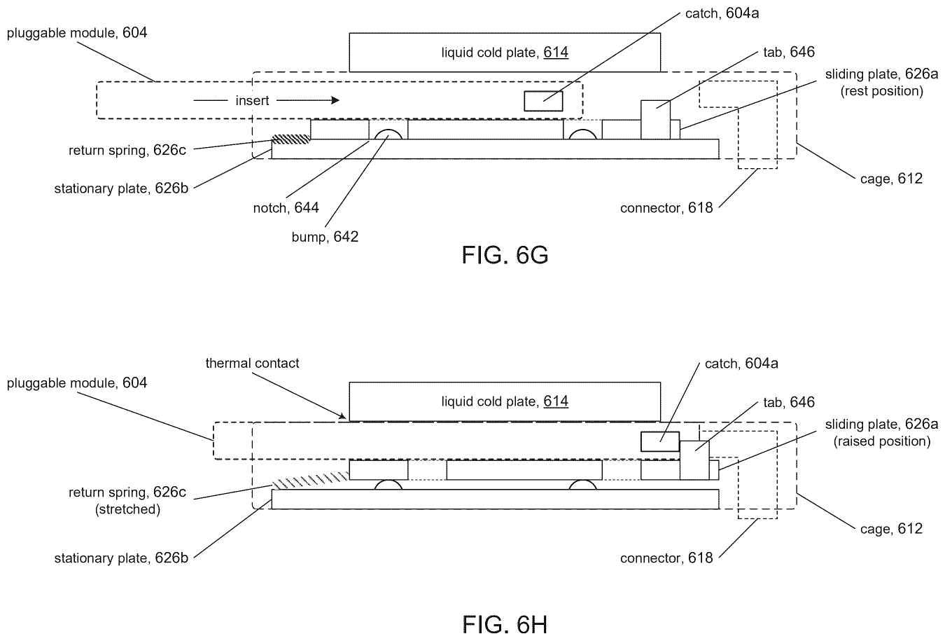

FIGS. 6A-6H show a cage assembly in accordance with a third example embodiment of the present disclosure. Cage assembly 600 is shown mounted on host PCB 602. Cage assembly 600 comprises cage 612 and a heat dissipation element which, in this embodiment, is liquid cold plate 614, although it will be appreciated that any suitable heat dissipation technique can be used. Liquid cold plate technology is known and briefly described above in connection with FIG. 4A. Connector 618 is mounted on PCB 602. A pluggable module (not shown) can plug into connector 618 to provide electrical connections to switching and supporting electronics (not shown) on PCB 602.

Cage 612 and liquid cold plate 614 have corresponding interlocking snap-fit features to provide a fixed attachment of the liquid cold plate to the cage so that the liquid cold plate is substantially immovable relative to the cage. It will be appreciated that any suitable attachment mechanism can be used such as gluing, spot welding, mechanical fastening (e.g., riveted, screw-mounted, etc.), and so on. In other embodiments, liquid cold plate 614 can be fixedly attached to PCB 602 so as to remain substantially immovable relative to the PCB; e.g., by mounting the liquid cold plate directly to the PCB with a standoff.

Referring to FIGS. 6B, 6C, and 6D, in this third example embodiment, the lifting mechanism is sliding mechanism 626 comprising sliding plate 626a and stationary plate 626b. Sliding plate 626a extends into interior volume 632 of cage 612 through opening 622a formed in cage floor 622. Stationary plate 626b can be mechanically attached to cage 612 (or to PCB 602) to remain substantially stationary relative to the cage (or the PCB). Return spring 626c connects sliding plate 626a to stationary plate 626b as shown in the detail in FIG. 6D.

FIGS. 6E and 6F are schematic illustrations showing additional details of sliding mechanism 626. Sliding plate 626a includes notches 644 that align with bumps 642 formed on stationary plate 626b when the sliding plate is in its rest position. Return spring 626c is attached to stationary plate 626b and sliding plate 626a. Return spring 626c pulls the sliding plate 626a into the rest position when a pluggable module is not plugged in. Bumps 642 can have any suitable shape that allows sliding plate 626a to slide over the bumps. In some embodiments, for example, bumps 642 can have a ramped or tapered profile.

FIGS. 6G and 6H are schematic illustrations showing the operation of sliding mechanism 626. FIG. 6G shows return spring 626c pulling sliding plate 626a to its rest position. In the rest position, bumps 642 line up with and fit into notches 644, allowing sliding plate 626a to rest atop stationary plate 626b. As illustrated in FIG. 6G, the components of cage assembly 600 can be dimensioned so that when sliding plate 626a is in the rest position, the separation between the sliding plate and liquid cold plate 614 allows pluggable module 604 to be inserted.

When pluggable module 604 is inserted into cage 612, catch 604a on the pluggable module will engage tab 646 on sliding plate 626a and push the sliding plate in the direction of insertion causing the sliding plate to slide over bumps 642. As sliding plate 626a slides over bumps 642, the sliding plate begins to rise which in turn lifts pluggable module 604 toward liquid cold plate 614. When pluggable module 604 is plugged into connector 618, sliding plate 626a will be fully raised on bumps 642 and pushing the pluggable module against liquid cold plate 614 to make thermal contact with the liquid cold plate. Bumps 642 can be designed with a height such that, when sliding plate 626a is resting on the bumps in the raised position, the sliding plate presses against pluggable module 604 with sufficient pressing force to create suitable thermal contact with liquid cold plate 614.

Return spring 626c is stretched as sliding plate 626a is pushed forward by pluggable module 604 during the insertion operation. The stretching of return spring 626c creates a restoring force in the spring that will pull sliding plate 626a back to the rest position upon removal of pluggable module 604.

Connector 618 (e.g., FIGS. 6G, 6H) can pivot or flex in order to be reoriented so as to accommodate the vertical displacement of pluggable module 604 as it is being plugged in. The lifting mechanism, in this case sliding plate 626, can be designed to take into account the force required to overcome any mechanical resistance presented by connector 618.

### Embodiment 4

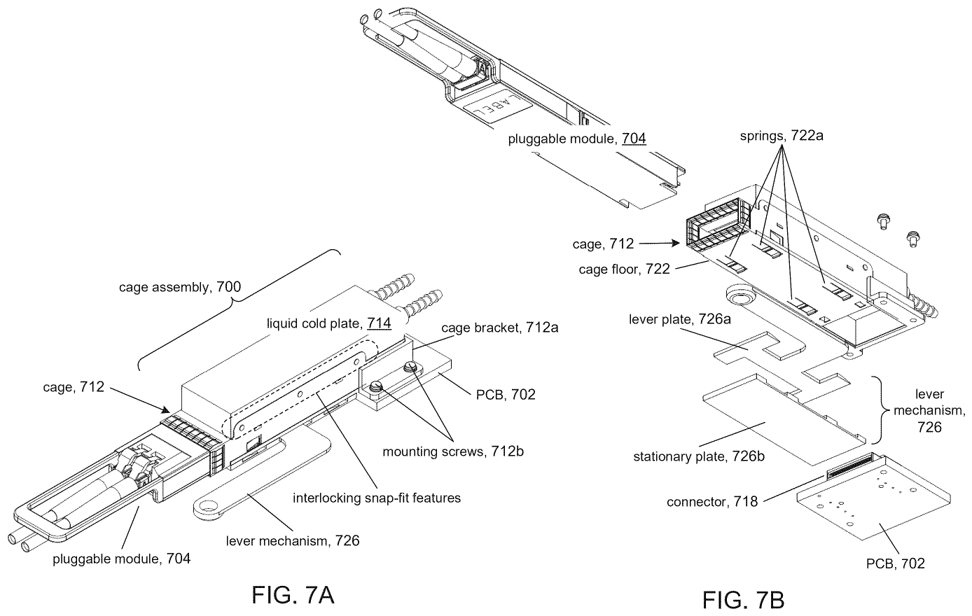

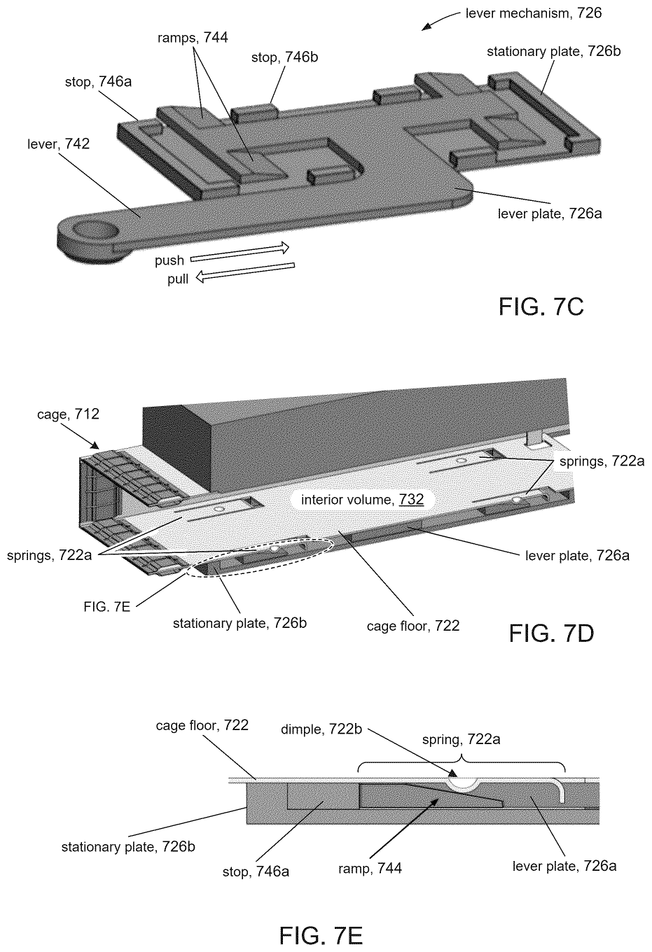

FIGS. 7A-7E show a cage assembly in accordance with a fourth example embodiment of the present disclosure. Cage assembly 700 is shown mounted on host PCB 702. Cage assembly 700 comprises cage 712 and a heat dissipation element comprising liquid cold plate 714; although it will be appreciated that any suitable heat dissipation technique can be used. Liquid cold plate technology is known and briefly described above in connection with FIG. 4A. Connector 718 is mounted on PCB 702. A pluggable module (not shown) can plug into connector 718 to provide electrical connections to switching and supporting electronics (not shown) on PCB 702.

Cage 712 and liquid cold plate 714 have corresponding interlocking snap-fit features to provide a fixed attachment of the liquid cold plate to the cage so that the liquid cold plate is substantially immovable relative to the cage. It will be appreciated that any suitable attachment mechanism can be used such as gluing, spot welding, mechanical fastening (e.g., riveted, screw-mounted, etc.), and so on. In other embodiments, liquid cold plate 714 can be fixedly attached to PCB 702 so as to remain substantially immovable relative to the PCB; e.g., by mounting the liquid cold plate directly to the PCB with a standoff.

In this fourth example embodiment, the lifting mechanism is user-activated lever mechanism 726 comprising lever plate 726a and stationary plate 726b. As explained below, lever plate 726a engages springs 722a formed in cage floor 722 of cage 712 (see also the cutaway view of FIG. 7D). Stationary plate 726b can be mechanically attached to cage 712 (or to PCB 702) to remain substantially stationary relative to the cage (or PCB).

Cage assembly 700 can include cage bracket 712a and mounting screws 712b for mounting the cage assembly to PCB 702. Connector 718 is mounted on PCB 702. Pluggable module 704 can plug into connector 718 to provide electrical connections to switching and supporting electronics (not shown) on PCB 702.

Referring to FIGS. 7C, 7D, and 7E, schematic illustrations show the operation of lever mechanism 726. Lever mechanism 726 is user operated. Lever plate 726a includes lever 742 which the user can grasp to push on the lever plate or pull on the lever plate. The lever plate rests atop and slides on stationary plate 726b. Stops 746a, 746b formed on stationary plate 726b limit how far lever plate 726a can be pushed or pulled.

Springs 722a are formed in cage floor 722. Springs 722a have a cantilever design that can be flexed to pivot into interior volume 732 of cage 712. Lever plate 726a has ramps 744 that align with springs 722a. As can be seen in the magnified image of FIG. 7E, springs 722a have dimples or bumps 722b that ride on the sloped face of ramp 744.

Referring to FIG. 7E, when lever plate 726a is pulled back to stop 746a (rest or pulled out position), dimple 722b rests on the lower portion of ramp 744; the resiliency of spring 722a returns the spring to its resting position, substantially flush with cage floor 722. On the other hand, when lever plate 726a is pushed forward, ramp 744 will move forward and push on dimple 722b, which in turn pushes on spring 722a to pivot into interior region 732.

In operation, a user plugs pluggable module 704 into connector 718. The user then pushes on lever plate 726a which causes springs 722a to pivot into interior region 732. Springs 722a in turn lift pluggable module 704 toward liquid cold plate 714 to make thermal contact with the liquid cold plate, completing the insertion operation.

To remove pluggable module 704, the user first pulls on lever plate 726 which allows springs 722a to flex back to their rest position. This lowers pluggable module 704, separating it from liquid cold plate 714. The user can then disconnect pluggable module 704 from connector 718, completing the removal operation.

Connector 718 can pivot or flex in order to be reoriented so as to accommodate the vertical displacement of pluggable module 704 after it is plugged in and lifted toward liquid cold plate 714.

### Embodiment 5

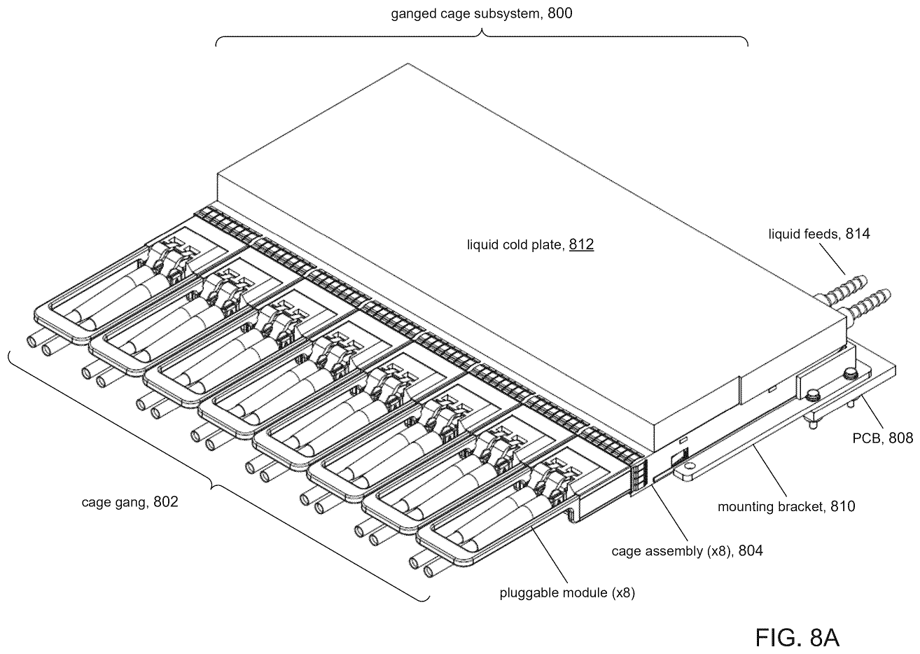

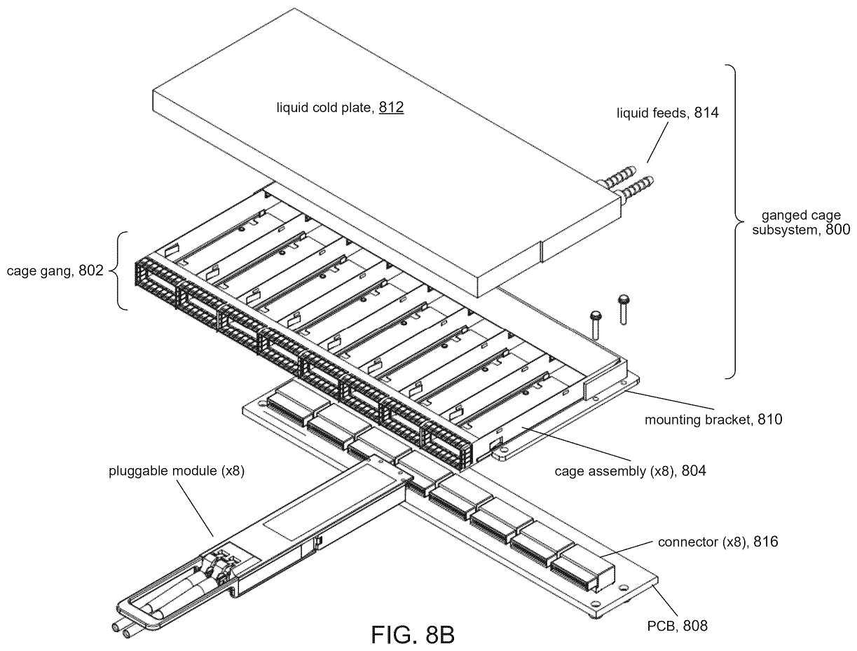

FIGS. 8A and 8B show a ganged cage subsystem in accordance with a fifth example embodiment of the present disclosure. In some embodiments, cage subsystem 800 comprises cage gang 802 comprising a set of cage assemblies 804 of the present disclosure. Although eight cage assemblies 804 are shown, it will be appreciated that there can be more or fewer cage assemblies in other embodiments. FIG. 8A shows pluggable modules plugged into each cage assembly 804.

Cage subsystem 800 further comprises a single liquid cold plate 812 that spans across cage assemblies 804, rather than having individual cold plates for each cage assembly. The single liquid cold plate configuration requires only one pair of liquid feeds 814 to provide cooling for cage assemblies 804, thus significantly reducing the mechanical structures needed to cool cage assemblies 804.

Cage subsystem 800 can be mounted to host PCB 808 by mounting bracket 810. The exploded view in FIG. 8B reveals connectors 816 mounted on PCB 808 corresponding to respective cage assemblies 804 for receiving respective pluggable modules 806.

### Embodiment 6

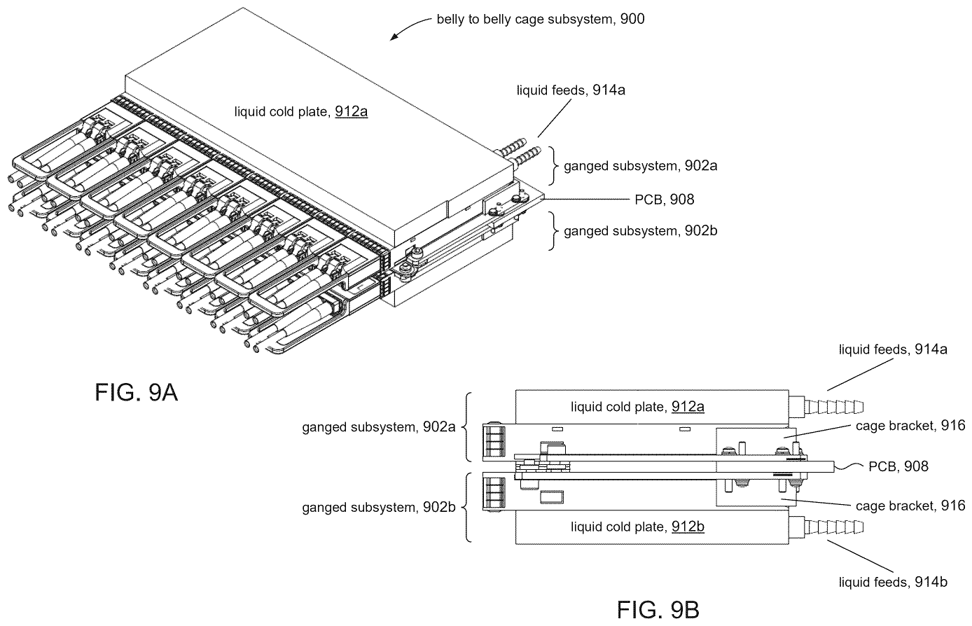

FIGS. 9A and 9B show a belly to belly cage subsystem in accordance with a sixth example embodiment of the present disclosure. In some embodiments, cage subsystem 900 comprises two ganged cage subsystems 902a, 902b, such as cage subsystem 800 shown in FIG. 8A for example. Cage subsystem 900 is a “belly to belly” configuration in that one ganged cage subsystem (e.g., 902b) is flipped upside down relative to the other ganged cage subsystem. Each ganged cage subsystem 902a, 902b is mounted to a common host PCB 908 via cage brackets 916. This configuration allows liquid cold plates 912a, 912b to be mounted to their respective ganged cage subsystems 902a, 902b, while at the same time allowing single-height connectors, such as connectors 816 (FIG. 8B), to attach to PCB 908.

### Embodiment 7

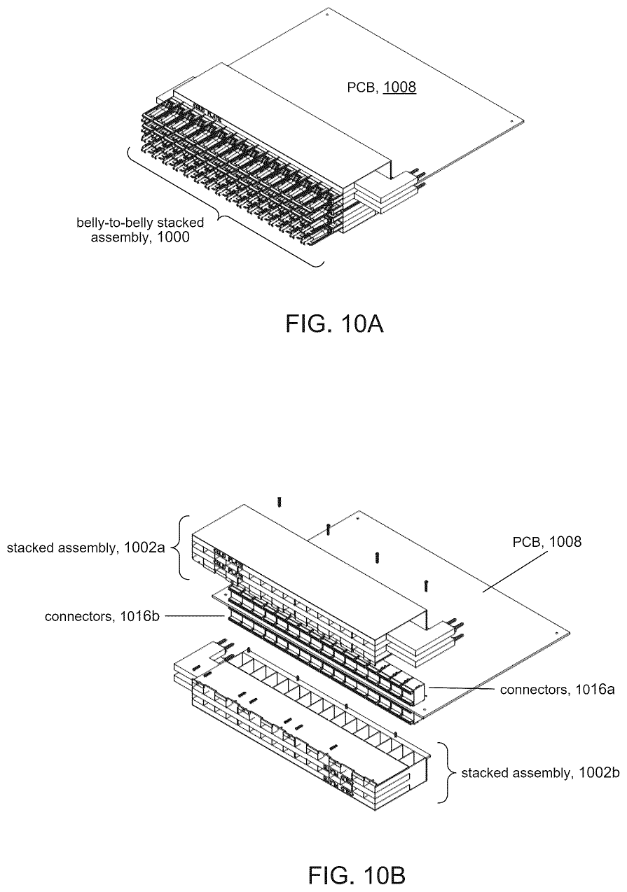

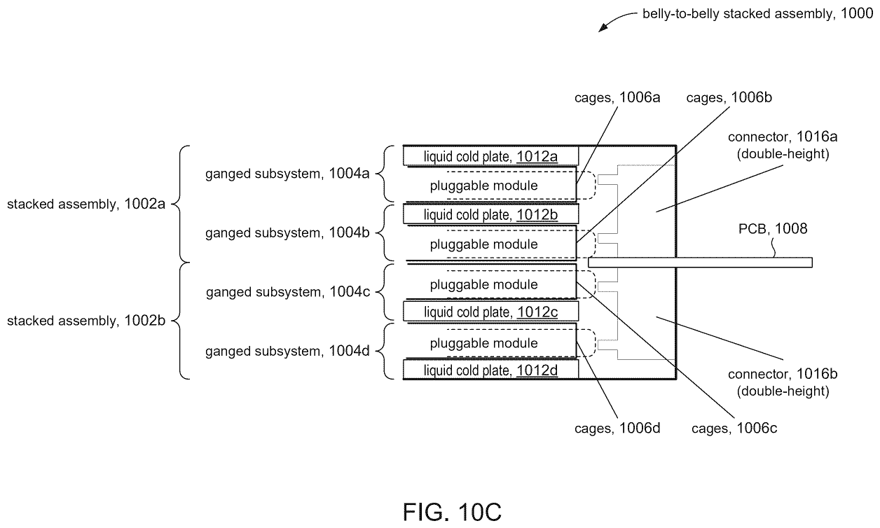

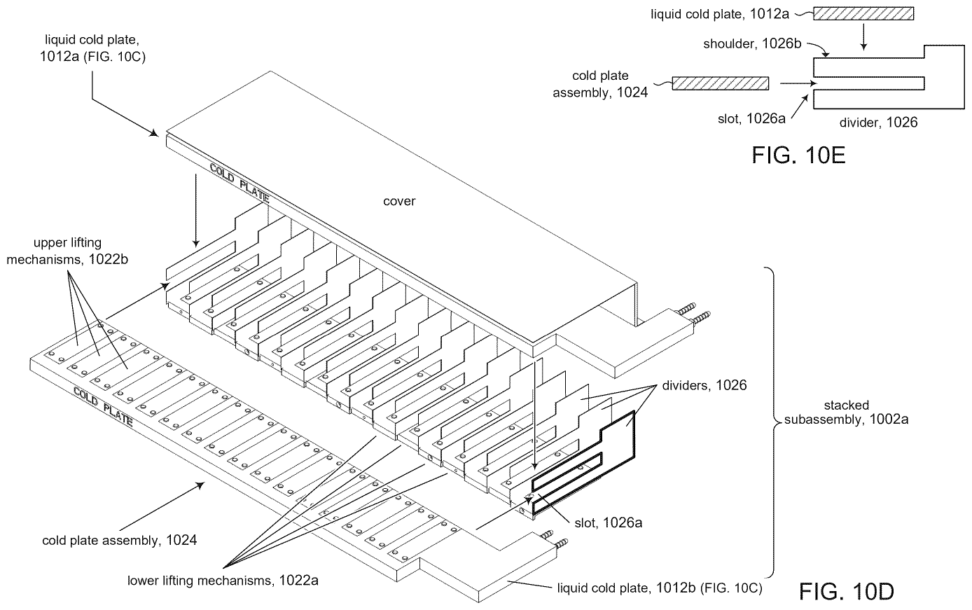

FIGS. 10A to 10E show a belly to belly stacked cage subsystem in accordance with a seventh example embodiment of the present disclosure. Belly to belly stacked cage subsystem 1000 comprises stacked assemblies 1002a, 1002b. Stacked assembly 1002a shares PCB 1008 with stacked assembly 1002b.

Each stacked assembly 1002a, 1002b comprises a pair of ganged stacked subsystems. For example, stacked assembly 1002a comprises ganged subsystems 1004a, 1004b stacked on top of each other. Likewise, stacked assembly 1002b comprises ganged subsystems 1004c, 1004d stacked on top of each other. Each ganged subsystem 1004a-1004d can be configured similar to ganged cage subsystem 800 shown in FIG. 8A. For example, FIG. 10C shows ganged subsystem 1004a comprises liquid cold plate 1012a and a corresponding row of cages 1006a that spans the liquid cold plate, ganged subsystem 1004b comprises liquid cold plate 1012b and a corresponding row of cages 1006b that spans the liquid cold plate, ganged subsystem 1004c comprises liquid cold plate 1012c and cages 1006c, and ganged subsystem 1004d comprises liquid cold plate 1012d and cages 1006d. Stacked assemblies 1002, 1002 can be configured in belly to belly configuration. FIG. 10B shows stacked assembly 1002b is flipped with respect to stacked assembly 1002a and attached to host PCB 1008.

Each connector 1016a in the row of connectors for stacked assembly 1002a is a double-height connector which can accommodate stacked pluggable modules, one from each ganged subsystem 1004a, 1004b. Likewise, each double-height connector 1016b in the row of connectors for stacked assembly 1002b can accommodate two pluggable modules from each ganged subsystem 1004c, 1004d.

FIGS. 10D and 10E show additional details of stacked subassembly 1002a (FIG. 10C) absent the row of cages (and likewise stacked assembly 1002b) constructed in accordance with some embodiments. Stacked subassembly 1002a comprises a row of lower lifting mechanisms 1022a and a set of dividers 1026 disposed between them. Each divider 1026 includes slot 1026a and shoulder 1026b. Stacked subassembly 1002a further comprises cold plate assembly 1024 which fits into slots 1026a of dividers 1026. Liquid cold plate 1012a rests on shoulders 1026b of dividers 1026.

Cold plate assembly 1024 comprises liquid cold plate 1012b which spans the width of the stacked subassembly 1002a. Cold plate assembly 1024 further comprises a set of upper lifting mechanisms 1022b integrated with liquid cold plate 1012b. Upper lifting mechanisms 1022b are spaced apart across the width of liquid cold plate 1012b and aligned with the spacing between dividers 1026 so that each upper lifting mechanism fits between a pair of the dividers when lower cold plate assembly 1024a slots into slots 1026a.

Referring to FIG. 10C, liquid cold plate 1012a and upper lifting mechanisms 1022b constitute ganged subsystem 1004a. Likewise, liquid cold plate 1012b and lower lifting mechanisms 1022a constitute ganged subsystem 1004b.

### Embodiment 8

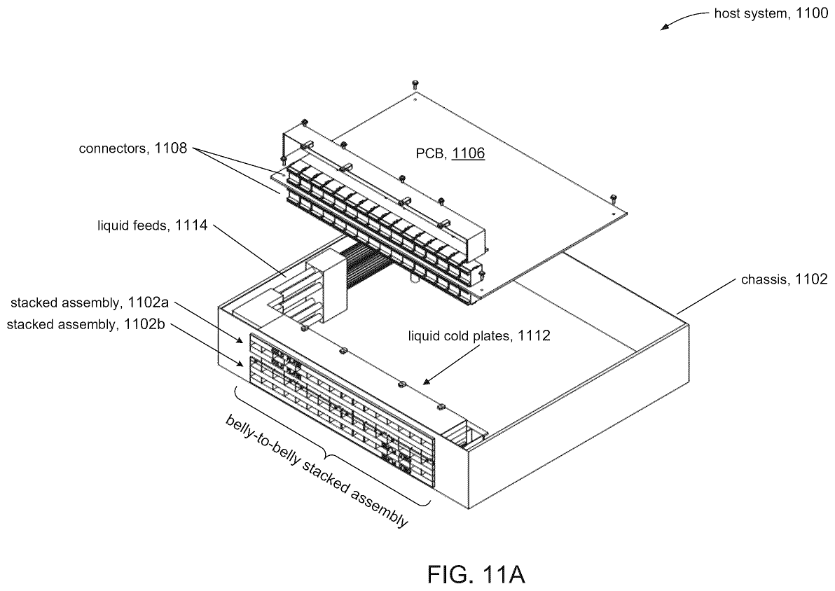

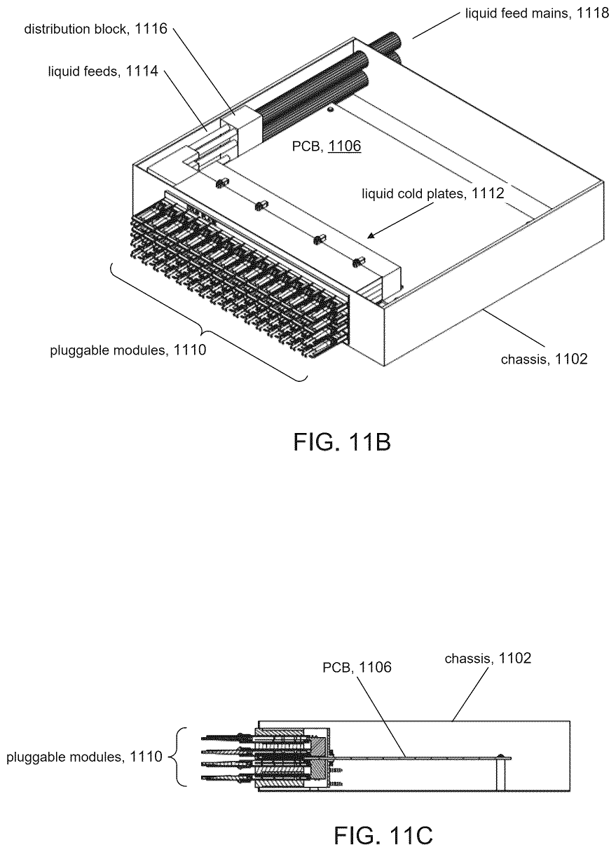

FIGS. 11A to 11C show views of a host system in accordance with an eighth embodiment of the present disclosure. Host system 1100 comprises a belly-to-belly stacked assembly similar to assembly 1000 shown in FIG. 10A. The exploded view of host system 1100 in FIG. 11A shows that stacked assemblies 1102a, 1102b can be pre-installed in chassis 1102 before installing host PCB 1106 which carries the switching electronics (not shown) and connectors 1108 for pluggable modules 1110.

The assembled view in FIG. 11B shows that corresponding liquid feeds 1114 for liquid cold plates 1112 of stacked assemblies 1102a, 1102b are connected to fluid distribution block 1116. Liquid feed mains 1118 include a cool fluid intake line to provide cool liquid from a heat exchange unit (not shown) to distribution block 1116 for distribution to the cool fluid intake lines of liquid feeds 1114. Distribution block 1116 receives heated liquid from the heated fluid return lines of liquid feeds 1112 which then feeds the heated liquid to a heated fluid return line of liquid feed mains 1118 to be cooled by the heat exchange unit.

### Embodiment 9

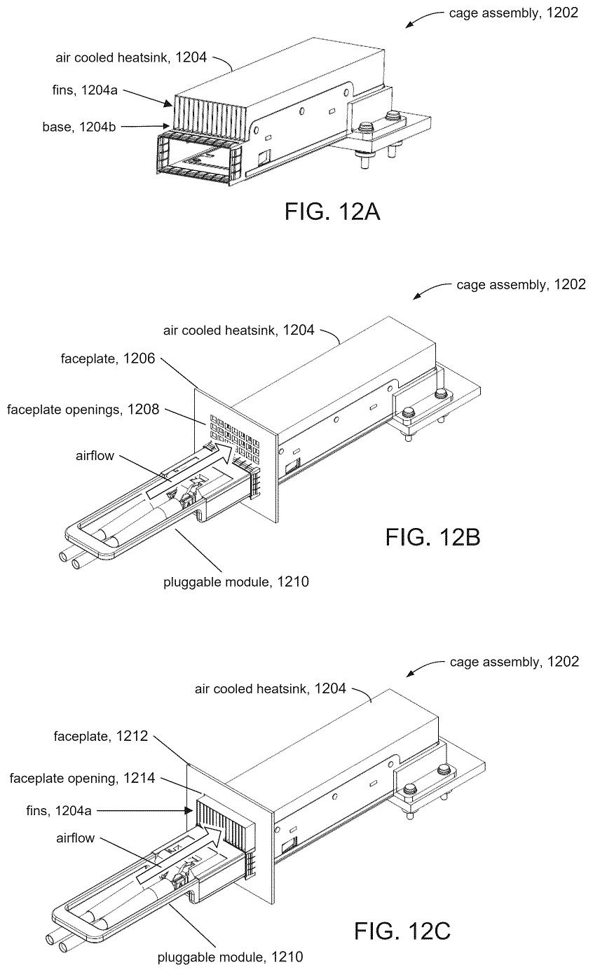

FIGS. 12A to 12C show views of a cage assembly in accordance with a ninth embodiment of the present disclosure. Cage assembly 1202 comprises air cooled heatsink 1204 as the heat dissipation element, instead of the liquid cold plate shown in previously described embodiments. Air cooled heatsink 1204 comprises a set of heat dissipation fins 1240a formed on a base plate 1204b, wherein a portion of base plate is exposed through an opening at the top of the cage (e.g., 412a, FIG. 4D). In this ninth embodiment, faceplate (front panel) 1206 of a chassis (e.g., 1102, FIG. 11A) includes a set of faceplate openings 1208 aligned with air cooled heatsink 1204. A flow of air enters faceplate openings 1208 to pass across fins 1204a to remove heat generated by pluggable module 1210 and picked up by the fins. FIG. 12C shows an alternative faceplate 1212 having a large faceplate opening 1214 through which fins 1204a can pass and be exposed to ambient air.

### Embodiment 10

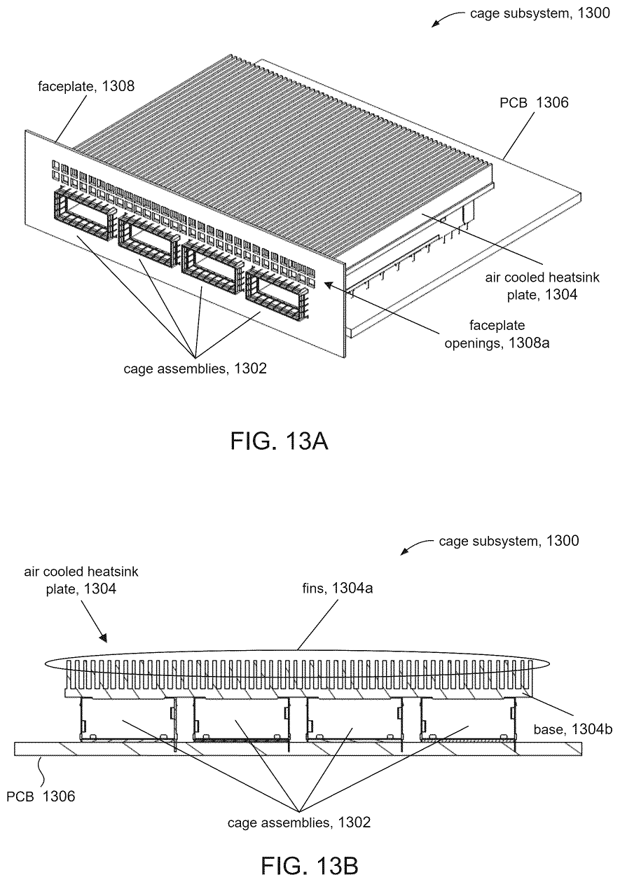

FIGS. 13A and 13B show views of a cage subsystem in accordance with a tenth embodiment of the present disclosure. Cage subsystem 1300 comprises individual cage assemblies 1302 of the present disclosure (mounted on host PCB 1306) where air cooled heatsink plate 1304 is the heat dissipation element. In accordance with this tenth embodiment, air cooled heatsink plate 1304 is a single component that spans the width of cage assemblies 1302, rather than using individual heat dissipation elements for each cage assembly.

Air cooled heatsink 1304 comprises a set of heat dissipation fins 1304a formed on a base plate 1304b. In this tenth embodiment, faceplate 1308 of a chassis (e.g., 1102, FIG. 11A) includes a set of faceplate openings 1308a aligned with air cooled heatsink plate 1304. A flow of air enters faceplate openings 1308a and passes across fins 1304a to remove heat.

The above description illustrates various embodiments of the present disclosure along with examples of how aspects of the present disclosure may be implemented. The above examples and embodiments should not be deemed to be the only embodiments, and are presented to illustrate the flexibility and advantages of the present disclosure as defined by the following claims. Based on the above disclosure and the following claims, other arrangements, embodiments, implementations and equivalents may be employed without departing from the scope of the disclosure as defined by the claims.

1. A pluggable module cage assembly in a network device, the cage assembly comprising:
a cage configured to receive a pluggable module;
a heat dissipation element fixedly attached to a first side of the cage, wherein the heat dissipation element is substantially immobile relative to the cage, at least a portion of the heat dissipation element exposed to an interior volume of the cage through the first side of the cage; and
a module lifting mechanism disposed at a second side of the cage opposite the heat dissipation element,
wherein, upon insertion of a pluggable module into the cage, the module lifting mechanism engages the pluggable module and moves the pluggable module toward the heat dissipation element.

2. The cage assembly of claim 1, wherein the module lifting mechanism presses the pluggable module against the exposed portion of the heat dissipation element to make thermal contact with the heat dissipation element.

3. The pluggable module cage assembly of claim 1, wherein the lifting mechanism comprises a plurality of spring clips disposed at the second side of the cage that protrude into the interior volume of the cage, wherein the spring clips engage with the pluggable module by exerting a pushing force on the pluggable module that moves the pluggable module toward the heat dissipation element.

4. The pluggable module cage assembly of claim 1, wherein the lifting mechanism comprises a pedestal and a spring-loaded retainer,
the second side of the cage having an opening therethrough, wherein the spring-loaded retainer supports the pedestal at the second side of the cage such that a portion of the pedestal extends into the interior volume of the cage,
wherein the pedestal engages with the pluggable module by virtue of the spring-loaded retainer exerting a pushing force on the pedestal to exert a pushing force on the pluggable module that moves the pluggable module toward the heat dissipation element.

5. The pluggable module cage assembly of claim 4, wherein the pedestal includes a plurality of heat dissipation fins formed on an exterior side of the pedestal.

6. The pluggable module cage assembly of claim 1, wherein the heat dissipation element is a liquid cold plate.

7. The pluggable module cage assembly of claim 1, wherein the heat dissipation element is an air cooled element comprising a base plate and heat dissipation fins.

8. The pluggable module cage assembly of claim 1, wherein the first side of the cage has an opening through which the portion of the heat dissipation element is exposed to the interior volume of the cage.

9. The pluggable module cage assembly of claim 1, wherein the first side of the cage comprises the heat dissipating element itself.

10. A pluggable module cage assembly, the cage assembly comprising:
a cage configured to receive a pluggable module;
a heat dissipation element fixedly attached to a first side of the cage, wherein the heat dissipation element is substantially immobile relative to the cage, at least a portion of the heat dissipation element exposed to an interior volume of the cage through the first side of the cage; and
a plurality of spring clips disposed at a second side of the cage opposite the first side that protrude into the interior volume of the cage,
wherein, upon insertion of a pluggable module into the cage, the spring clips engage with the pluggable module by exerting a pushing force on the pluggable module that moves the pluggable module toward the heat dissipation element.

11. The pluggable module cage assembly of claim 10, wherein the plurality of spring clips press the pluggable module against the exposed portion of the heat dissipation element to make thermal contact with the heat dissipation element.

1. The pluggable module cage assembly of claim 10, wherein the heat dissipation element is a liquid cold plate.

2. The pluggable module cage assembly of claim 10, wherein the first side of the cage has an opening through which the portion of the heat dissipation element is exposed to the interior volume of the cage.

3. The pluggable module cage assembly of claim 10, wherein the first side of the cage comprises the heat dissipating element itself.

4. A pluggable module cage assembly, the cage assembly comprising:
a cage configured to receive a pluggable module;
a heat dissipation element fixedly attached to a first side of the cage, wherein the heat dissipation element is substantially immobile relative to the cage, at least a portion of the heat dissipation element exposed to an interior volume of the cage through the first side of the cage;
a pedestal; and
a spring-loaded retainer that supports the pedestal at a second side of the cage opposite the first side, wherein a portion of the pedestal extends into the interior volume of the cage through an opening formed through the second side of the cage,
wherein, upon insertion of a pluggable module into the cage, the pedestal engages with the pluggable module by virtue of the spring-loaded retainer exerting a pushing force on the pedestal that in turn exerts a pushing force on the pluggable module which moves the pluggable module toward the heat dissipation element.

5. The pluggable module cage assembly in claim 15, wherein the pedestal presses the pluggable module against the exposed portion of the heat dissipation element to make thermal contact with the heat dissipation element.

6. The pluggable module cage assembly in claim 15, wherein the pedestal includes a plurality of heat dissipation fins formed on an exterior side of the pedestal.

7. The pluggable module cage assembly in claim 15, wherein the heat dissipation element is a liquid cold plate.

8. The pluggable module cage assembly in claim 15, wherein the first side of the cage has an opening through which the portion of the heat dissipation element is exposed to the interior volume of the cage.

9. The pluggable module cage assembly in claim 15, wherein the first side of the cage comprises the heat dissipating element itself.
